(19) United States
(12) Patent Application Publication
(10) Pub. No.: US 2013/0070551 A1
(43) Pub. Date: Mar. 21, 2013

(54) Percolation Tamper Protection Circuit for Electronic Devices

(71) Applicant: QorTek, Inc., Williamsport, PA (US)

(72) Inventors: Ross Bird, Canton, PA (US); Greg Bower, State College, PA (US); Gareth J. Knowles, Williamsport, PA (US); Jonathan Zook, Muncy, PA (US)

(73) Assignee: QorTek, Inc., Williamsport, PA (US)

(21) Appl. No.: 13/621,741

(22) Filed: Sep. 17, 2012

Related U.S. Application Data
(60) Provisional application No. 61/535,577, filed on Sep. 16, 2011.

(51) Int. Cl. G11C 5/14

(52) U.S. Cl. 365/228

(57) ABSTRACT

An integrated circuit employing a percolation tamper protection device includes a circuit housing with a die disposed in circuit housing. The die includes a volatile memory. A percolation tamper protection device that is connected to the volatile memory and also disposed in the circuit housing. The percolation tamper protection device includes a percolation gate which is biased in a conductive state. The percolation gate includes a first terminal that is connected to the volatile memory and a second terminal configured to be connected to a power supply. The percolation gate has a conductivity that varies proportional to pressure.

This application claims priority to U.S. patent application Ser. No. 61/535,577 filed on Sep. 16, 2011, which is incorporated by reference herein in its entirety.

### I. FIELD OF THE INVENTION

The invention relates to prevention of access to electronically stored data. More particularly, the invention is relates to protection of high-level devices such as FPGA, ASIC and microcontroller microchips or systems boards containing said microchips.

### II. BACKGROUND OF THE INVENTION

Logic circuits, microprocessor cores, memory controllers, accelerators, etc., are an assembly of combinatorial logic functions and flip-flops (registers). An FPGA, ASIC or microcontroller can be configured to implement a very large interconnected array of such circuits and connect itself to the outside world. A fundamental issue is to protect the proprietary information contained within this interconnected array (bit map states). When a user successfully authenticates the cryptosystem or authentication key the encryption is unlocked and passed to a cryptographic filter. However, if the allocated memory subsection/program within a programmable chip can be accessed, there creates an unauthorized ability to extract the cryptographic keys and to decrypt and analyze the information using a variety of tools and procedures. Access to the key allows an attacker to disable security on the microchip, modify low-level silicon features, access unencrypted configuration bitstream or even permanently damage the device. If an attacker can take control of a high-level device, the attacker can then erase or even physically destroy the device by uploading a malicious bitstream that will cause a high current to pass through the device and burn it out. The attacker can alternatively extract the proprietary data from the device and make some changes to the firmware. The attacker can also enable a clone or reprogram the design, possibly introducing a Trojan so as to carry out more sophisticated attacks at a later date.

A primary issue is that a cryptosystem (secure key) code is accessible when system power is on, retained or backed up for long periods when the system power is shut down. Thus it is desirable to prevent any unauthorized ability to extract the cryptographic keys as to decrypt and analyze the information during such operations using a variety of tools and procedures. An ongoing goal of industry and defense is to integrate some form of attack detection mechanism, that, if triggered, will then cause erasure (‘wipe’) of critical data as to prevent access.

Some prior art devices provide a solution by implementing a scheme for data erasure of the key microchip e.g., ASIC or FPGA, memory code information by storing all of the sensitive data onto a separate independent memory from the encryption data engine, either in volatile or non-volatile format. Such prior art devices then utilize a trigger from an anti-tamper detection system that is physically separate from both the encryption data and either the separate key data device itself or the encryption data engine processor.

Recent revelations of vulnerability of static ROM based encryption data has lead some to store the critical data sets within volatile memory. Most forms of modern random access memory (RAM) are volatile storage, including dynamic random access memory (DRAM) and static random access memory (SRAM). Volatile RAM loses its data quickly when power is removed. For example, DRAM volatile memory refresh rate requires power availability every 8-64 msec, depending upon refresh scheme employed and DRAM architecture. However, in DRAM memory cells capacitors will often retain their values for significantly longer, particularly at low temperatures. This indicates that it will be preferable to store the critical key data in SRAM.

Although it is possible to erase the secure key code, or other, information upon detection of a tamper event with the use of either volatile or non-volatile memory, it can be problematic. When resetting the individual bits to a logic ‘0’, individual memory bits will nevertheless retain some level of charge from their previous state (‘0’ or ‘1’) even upon power discontinuation. This opens up an array of reverse-engineering techniques, including i/o mapping, layer-by-layer removal, non-contact imaging etc. that can now be applied as to extract the previously stored key information.

Accordingly, there is a need for a device that can effectively erase critical data from FPGAs, ASICs and microcontrollers in the event of unauthorized access.

### III. SUMMARY OF THE INVENTION

In at least one embodiment, the invention includes a percolation tamper protection circuit comprising a percolation gate, first and second terminals and a volatile memory. The percolation gate includes a pressure conduction composite that has a conductivity that varies proportional to pressure and the percolation gate has a first short circuit state and a second open circuit state. First and second terminals are connected to the percolation gate, where the first terminal is configured for connection to a power supply. A volatile memory is connected to the second terminal whereby current is choked from said volatile memory when said percolation gate switches states thereby erasing data stored in said volatile memory.

In at least one embodiment the invention includes a percolation tamper protection circuit which includes a percolation gate comprising a pressure conduction composite that generates a stress induced output voltage responsive to pressure. First and second terminals are connected to the percolation gate, where the first terminal is configured for connection to a power supply. A volatile memory containing data to be protected is connected to the second terminal. A means for determining whether the stress induced output voltage is indicative of a tamper event is provided that chokes current flow from the power supply to the volatile memory when it is determined that the stress induced output voltage is indicative of a tamper event thereby causing erasure of data stored in said volatile memory.

In at least one embodiment, the invention includes an integrated circuit employing a percolation tamper protection device. The integrated circuit has a housing enclosing a die and a percolation tamper protection device. The die includes a volatile memory. The percolation tamper protection device is connected to the volatile memory and includes a percolation gate that has a conductivity that varies proportional to pressure and first and second terminals connected to the percolation gate. A packing lid is mounted to the housing. The packing lid includes a plurality of pressure amplifiers that compress the percolation gate creating a preload that biases the percolation gate into a near short circuit state.

In at least one embodiment, the invention includes an integrated circuit employing a percolation tamper protection device. The integrated circuit has a housing enclosing a die and the percolation tamper protection device. The die includes a volatile memory. The percolation tamper protection device is connected to the volatile memory and includes a percolation gate that is biased in a conductive state and that has a conductivity that varies proportional to pressure

### IV. BRIEF DESCRIPTION OF THE DRAWINGS

FIG. 1 is a block diagram of a tamper protection device of the present invention.

FIG. 2 illustrates an equivalent circuit diagram of a JFET-type tamper protection device of the present invention.

FIG. 3a illustrates a percolation tamper device in accordance with the invention.

FIG. 3b shows an interdigitated electrode in accordance with the invention.

FIG. 4 shows a block diagram of a logic-controlled JFET-type tamper protection device of the present invention.

FIG. 5 depicts a tamper protection device in accordance with the present invention disposed within a microelectronics package.

### V. DETAILED DESCRIPTION OF THE EMBODIMENTS

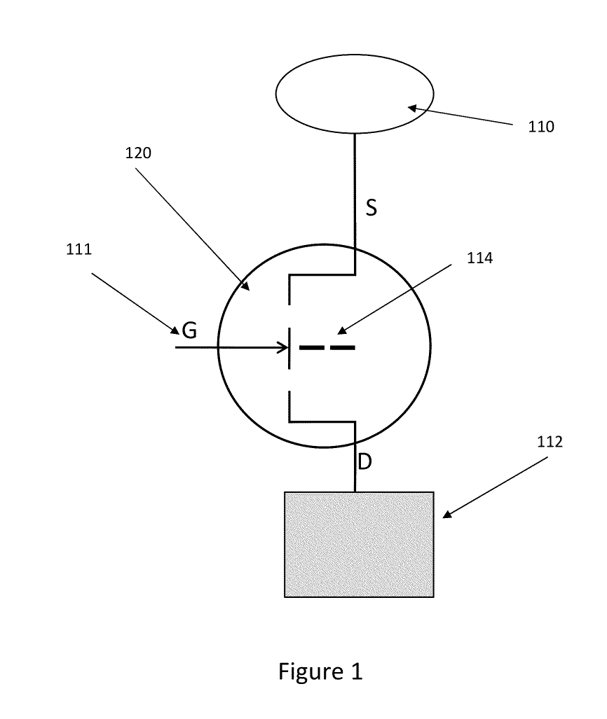

FIG. 1 illustrates a percolation tamper protection circuit in accordance with the invention. The percolation tamper protection circuit generally comprises a voltage source 110 coupled to a percolation tamper protection device 120 which in turn is connected to volatile memory 112. The percolation tamper protection device 120 comprises a two terminal device that changes the conduction between the terminals dependent on applied pressure (stress). In one embodiment, the percolation tamper protection device 120 is similar in operation to a MOSFET or JFET device and similarly comprises a percolation gate 111 that varies the conduction path 114 between a voltage source 110 and a volatile memory drain 112 and first and second terminals S and D. Percolation gates are sometimes referred to as percolation materials/mechanisms or pressure conduction composites. Any such percolation material or mechanism can be used to functionally implement the percolation gate 111. In the percolation tamper protection circuit of FIG. 1, the voltage source 110 is of sufficient conditioned dc voltage as to be capable of supporting volatile memory 112, which comprises the drain load.

A conduction path 114 supplies current from power supply 110 to volatile memory 112. Percolation gate 111 alters conduction path 114 in response to physical stress. As with gate voltage of a transistor device, provided the physical stress on percolation gate 111 is above the percolation threshold, percolation gate 111 allows for conduction and dc voltage is supplied to the volatile memory 112 from source 110. As stress is reduced on percolation gate 111 the conduction path will constrict until a point at which insufficient voltage is supplied to support the volatile memory 112 thereby causing the bit states of volatile memory 112 to revert to their null state. While not intending to be bound by theory, it is believed that due to the high Q nature of percolation materials, a very small change in stress around the percolation threshold will cause free flow of electrons through percolation gate 111 to be constricted.

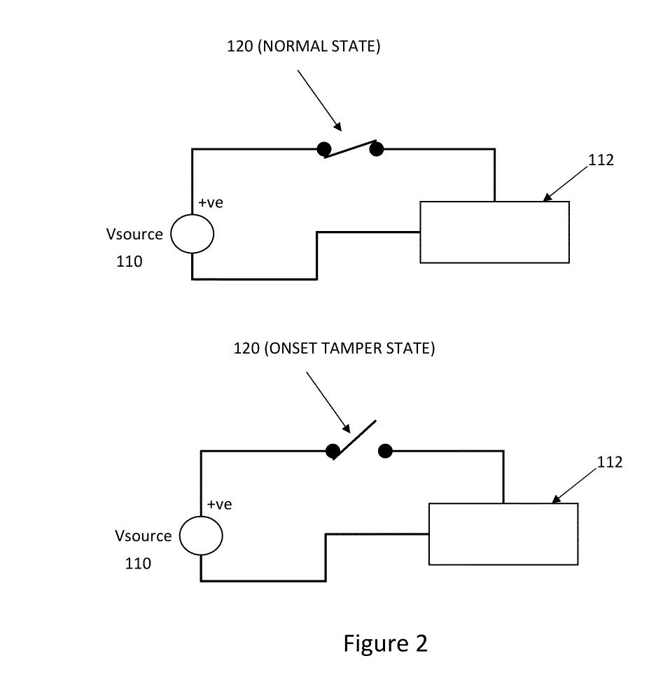

FIG. 2 illustrates a functional diagram showing the switchmode operation of a JFET-type percolation tamper protection device 120. The schematic shows the percolation tamper protection device 120 in its linear region operating as a two-state switch that connects the source 110 to the volatile memory 112. In JFET type percolation tamper protection device 120, its normal state is attained when there is a loading or stress condition on the percolation gate 111 as to ensure that the device is sufficiently above its percolation threshold as to enable sufficient potential difference between percolation tamper protection device 120 and ground as to support the bit storage in the volatile memory 112. In such a condition percolation tamper protection device 120 can be considered as effectively a short circuit. If the loading or stress condition on the percolation gate 111 drops below the volatile memory percolation threshold corresponding to enabling sufficient potential difference between percolation tamper protection device 120 and ground as to support retention of bit states then the bit states will be nulled and in this situation the percolation tamper protection device 120 can be considered as an open circuit. It is believed that due to the extremely high mechanical Q of percolation gate 111 in its linear region this change of states approximates a step function centered very slightly above the normal percolation threshold enabling percolation tamper protection device 120 to operate as a two-state device that mimics the behavior of a JFET device with applied pressure loading replacing applied voltage at the gate.

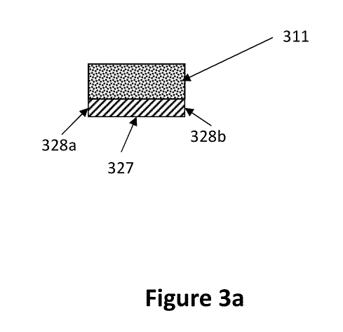

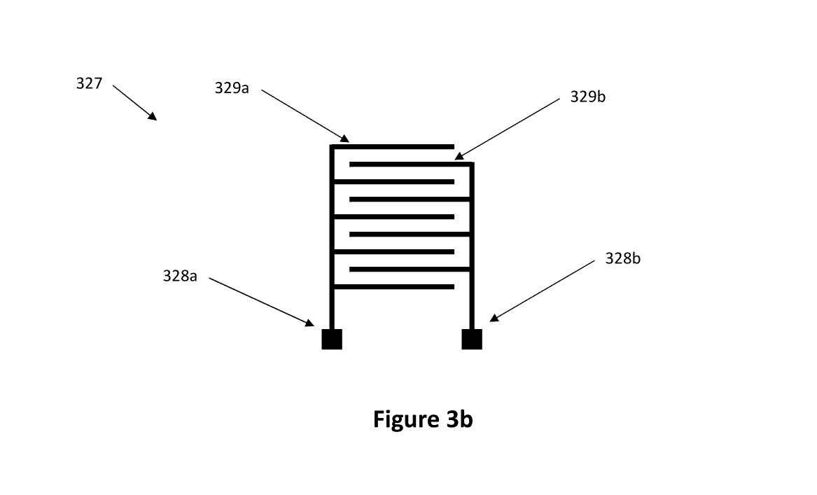

In accordance with an embodiment of the invention, as illustrated in FIG. 3a an exemplary percolation tamper protection device comprises a percolation gate 311 in contact with two or more terminal layers which, in some embodiments, comprise interdigitated traces 327. In other embodiments the terminal layers may include electrodes disposed on the top and bottom of percolation gate 31. In some embodiments, percolation gate 111 may be realized by the pressure conduction composite described in U.S. Pat. No. 7,080,562 which is herein incorporated by reference. Other pressure conduction composites and/or percolation materials or mechanisms that exhibit similar properties may be employed as percolation gate 111.

An exemplary interdigitated trace pair 327 comprising closely spaced first and second interdigitated trace terminals 328a and 328b is depicted in FIG. 3. Fingers 329a and 329b are provided on respective ends of trace terminals 328a and 328b and are typically manufactured from platinum, gold or other conductive materials.

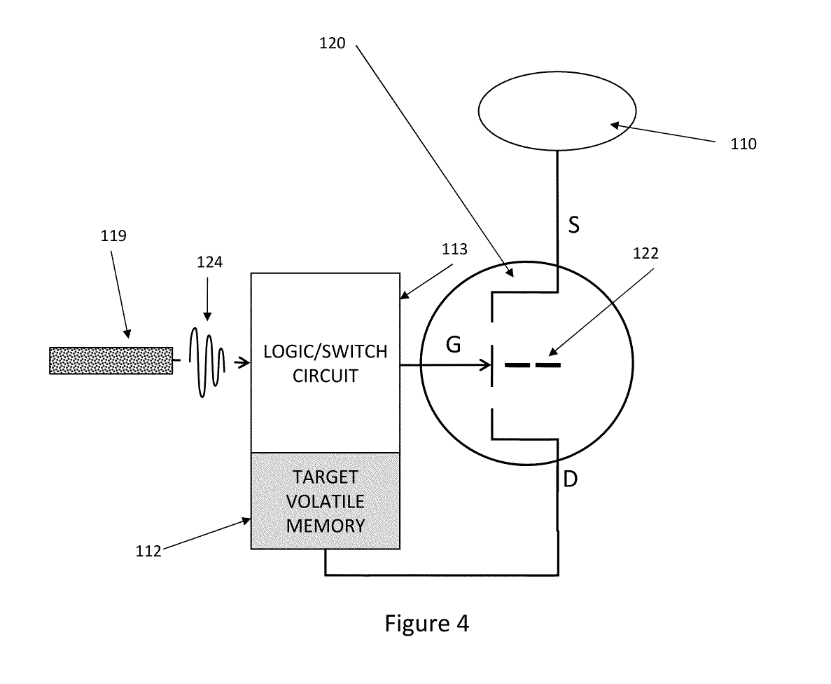

FIG. 4 illustrates another embodiment of a percolation tamper protection circuit in accordance with the invention. In this embodiment, a coupling tamper logic circuit 113 is interposed between percolation gate 111 and percolation grid 122 that represents the percolation grid between conduction and non-conduction states. A preferred embodiment of tamper logic 113 is acquired using Neural Network techniques. If power is interrupted output of percolation gate 111 is zero irrespective of the signal internally generated by tamper logic circuit 113 the output logic block sets to ‘high’ causing drain voltage to the volatile memory 112 to collapse. When a tamper event occurs it will cause a stress output voltage 124 to occur. This signal acts as input into the tamper logic circuit 113 that is normally embedded as part of the higher-level programmable component itself as a set of code lines. The tamper logic circuit makes a determination of whether or not the waveform 124 corresponds to an onset tamper event. If it is so determined with acceptable probability that it is indeed originating from an onset tamper event the output logic block sets to ‘high’ and current flow ceases. If it is so determined voltage signal does not correspond to an onset tamper event the output logic block sets to ‘low’ and current flow continues uninterrupted.

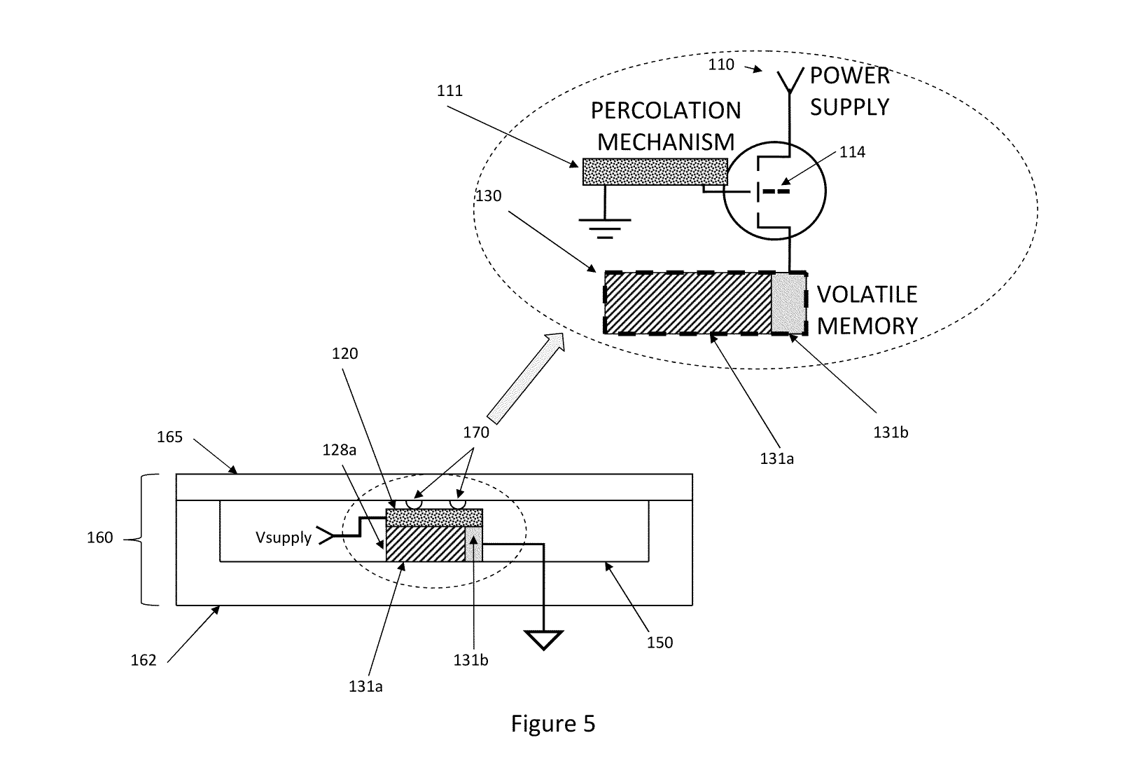

FIG. 5 depicts an embodiment of IC employing a JFET-type percolation tamper protection device in accordance with the invention. A die wafer 130, whose bit data is to be protected, is either partitioned as to provide a nonvolatile component 131a and volatile component 131b, or augmented with a distinct volatile memory device. Suitable volatile memory includes dynamic random access memory (DRAM) or static random access memory (SRAM). In either case volatile component 131b contains the secure key code. In the configuration shown in FIG. 5 a JFET type percolation tamper protection device 120 is co-packaged with the die(s) 130. The percolation tamper protection device 120 and the installed die wafer 130 are disposed within conventional open cavity microelectronics package 160 comprising a package housing 162 and a package lid 165 in a manner as to ensure that a preload applies sufficient pressure to percolation tamper protection device 120 as to place percolation gate 111 in its linear region near its short circuit state depicted in FIG. 2. In this state the gate conduction is sufficient to allow the voltage source 110 to provide necessary power to volatile component 131b so as to maintain the present bit state. The drain terminal D of the percolation tamper protection device 120 connects to the power terminal of one or more volatile die or die regions 131b.

In keeping with the invention, to ensure that percolation tamper protection device 120 is in its normal conduction region, passive amplifiers 170 are interposed between packaging lid 165 and percolation tamper protection device 120 and percolation tamper protection device 120 is disposed contiguous to and stacked on top of die 130. The number and physical dimensions of such pressure amplifiers 170 control the loading magnitude on the percolation gate 111. For ceramic packaged devices, packaging lid 165 may be provided with two or more pressure amplifiers 170 spaced from each other.

The voltage source 110 may be internal or external to package 160. Suitable internal cavity exemplary voltage sources include long-duration micro sources such as a betavoltaic or superhydrophobic nanostructured batteries. Voltage source 110 is selected as to be capable of producing sufficient power to sustain volatile memory 112 in this normal conduction mode.

Any physical attack on the IC chip; for example, if the device is pried off its circuit board for detailed analysis, or the device is undergoing milling as part of a device reconstruction reverse engineering effort, or the packaging lid 165 is simply tampered with as to inspect the chip will all cause reduction in stress loading on the percolation tamper protection device 120. This stress reduction will cause a very large drop in gate conduction resulting in a loss of support level voltage at volatile memory region 131b, thereby causing the bit data stored in volatile memory region 131b to revert to their null state. Repeated strain loss during a tamper event will cause the voltage across volatile region 131b to similarly go from high to low to high in a continuing repetitive fashion as to cause repeated erasure of the bit states therein.

If an attacker seeks to remove the power source 110 at any point in an attack, the voltage across volatile region 131b is zero and the data bits stored therein will instantly revert to their null state. If the attacker seeks to void such a result and make static the bit states in a zero voltage supply condition by drastically reducing the surrounding temperature of the IC 160, then due to the temperature dependence of percolation materials, the percolation gate 111 supply will have dropped below its percolation threshold much earlier in this process and will no longer allow for conduction from source to drain causing the data bits in volatile memory to revert to their null state.

As used above “substantially,” “generally,” “relatively” and other words of degree are relative modifiers intended to indicate permissible variation from the characteristic so modified. It is not intended to be limited to the absolute value or characteristic which it modifies but rather possessing more of the physical or functional characteristic than its opposite, and preferably, approaching or approximating such a physical or functional characteristic.

Although the present invention has been described in terms of particular embodiments, it is not limited to those embodiments. Alternative embodiments, examples, and modifications which would still be encompassed by the invention may be made by those skilled in the art, particularly in light of the foregoing teachings.

Those skilled in the art will appreciate that various adaptations and modifications of the embodiments described above can be configured without departing from the scope and spirit of the invention. Therefore, it is to be understood that, within the scope of the appended claims, the invention may be practiced other than as specifically described herein.

We claim:

1. A percolation tamper protection circuit comprising:
a percolation gate including a pressure conduction composite having a conductivity that varies proportional to pressure, said percolation gate having a first short circuit state and a second open circuit state;
first and second terminals connected to said percolation gate, the first terminal being configured for connection to a power supply;
a volatile memory connected to said second terminal, wherein current is choked from said volatile memory when said percolation gate switches states.

2. The percolation tamper protection circuit of claim 1 further comprising a power supply connected to said first terminal, wherein any interruption of said power supply causes a loss of voltage potential across the volatile memory.

3. The percolation tamper protection circuit of claim 1 wherein said first and second terminals comprise output terminals of interdigitated traces.

4. A percolation tamper protection circuit comprising:
a percolation gate including a pressure conduction composite that generates a stress induced output voltage responsive to pressure
first and second terminals connected to said percolation gate, the first terminal being configured for connection to a power supply;
a volatile memory connected to said second terminal, said volatile memory containing data;
means for determining whether the stress induced output voltage is indicative of a tamper event and choking current flow from said power supply to said volatile memory when it is determined that the stress induced output voltage is indicative of a tamper event thereby causing erasure of data stored in said volatile memory.

5. The percolation tamper protection circuit of claim 4 wherein said means for determining permits current flow from said power supply to said volatile memory when it is determined that the stress induced output voltage is not indicative of a tamper event.

6. An integrated circuit employing a percolation tamper protection device comprising:
a housing;
a die disposed within said housing, said die including a volatile memory;
a percolation tamper protection device connected to said volatile memory, said percolation tamper protection device including a percolation gate having a conductivity that varies proportional to pressure and first and second terminals connected to the percolation gate, said percolation tamper protection device disposed within said circuit housing;
a packing lid including a plurality of pressure amplifiers, said packing lid being mounted to said housing such that the plurality of pressure amplifiers compress said percolation gate creating a preload that biases the percolation gate into a near short circuit state.

7. The integrated circuit of claim 6 further comprising a power supply connected to said percolation tamper protection device and disposed within said housing.

8. The integrated circuit of claim 6 further comprising a power supply connected to said percolation tamper protection device and disposed external to said housing.

9. The integrated circuit of claim 6 wherein said percolation tamper protection device is stacked on top of said die.

10. An integrated circuit employing a percolation tamper protection device comprising:
a housing;
a die disposed within said housing, said die including a volatile memory;
a percolation tamper protection device connected to said volatile memory, said percolation tamper protection device including a percolation gate biased in a conductive state having a conductivity that varies proportional to pressure and having first and second terminals controlled by the percolation gate, said percolation tamper protection device disposed within said circuit housing.
